(19) United States
(12) Patent Application Publication
(10) Pub. No.: US 2025/0081319 A1
(43) Pub. Date: Mar. 6, 2025

(54) Light Source Using Pre-Ionization

(71) Applicants: Hamamatsu Photonics K.K., Shizuoka (JP); Energetiq Technology, Inc., Wilmington, MA (US)

(72) Inventors: Frederick Marvin Niell, III, Tampa, FL (US); David B. Reisman, Albuquerque, NM (US); Daniel J. Arcaro, Medford, MA (US); Donald K. Smith, Newton, MA (US); Michael J. Roderick, Everett, MA (US)

(73) Assignees: Hamamatsu Photonics K.K., Shizuoka (JP); Energetiq Technology, Inc., Wilmington, MA (US)

(21) Appl. No.: 18/586,458

(22) Filed: Feb. 24, 2024

Related U.S. Application Data
(60) Provisional application No. 63/579,701, filed on Aug. 30, 2023.

(51) Int. Cl. H05G 2/00; G03F 7/00

(52) U.S. Cl. CPC H05G 2/005; H05G 2/008; G03F 7/70033

(57) ABSTRACT

An EUV light source includes a chamber that defines a plasma confinement region. A magnetic core is positioned around the chamber and is configured to generate a plasma in the plasma generation region so that the plasma converges in the plasma confinement region. A power delivery section is positioned around the magnetic core. A power supply includes a charging circuit, a pre-ionization circuit, and a solid state switching circuit having an output coupled to the magnetic core. The power supply is configured to isolate the charging circuit from the power delivery section and to generate a pre-ionization pulse through inductive coupling that causes ionization of gas in the plasma generation region. The solid state switching circuit is configured to discharge a capacitance through inductive coupling to form a plasma in the plasma generation region.

### CROSS-REFERENCE TO RELATED APPLICATION

The present application is non-provisional of U.S. Provisional Patent Application No. 63/579,701 entitled “Extreme Ultra-Violet Light Source Using Pre-Ionization”, filed on Aug. 30, 2023. The entire contents of U.S. Provisional Patent Application No. 63/579,701 are herein incorporated by reference.

The section headings used herein are for organizational purposes only and should not be construed as limiting the subject matter described in the present application in any way.

### INTRODUCTION

Numerous commercial and academic applications have a need for high brightness light in the extreme ultra-violet (EUV) region of the spectrum. For example, EUV light is needed for numerous industrial applications, including metrology, accelerated testing, photoresist, defect inspection, and microscopy. Other applications for EUV light include microscopy, spectroscopy, areal imaging, and blank mask inspection. These and other applications require EUV sources that have high reliability, small physical size, low fixed cost, low operating cost, and low complexity from these important sources of extreme ultraviolet photons.

Known switched power supplies have limited the performance and usefulness of these high brightness light in the extreme ultra-violet (EUV) region of the spectrum because they use magnetic switches which are well known in the art to have numerous performance disadvantages including that they are relatively slow and physically large. New switched power supplies are required to advance the performance of these high brightness EUV light sources.

### SUMMARY

An extreme ultra-violet light source includes a chamber comprising a high voltage region, a low voltage region, a plasma generation region that defines a plasma confinement region, and a port that allows light generated by the plasma to propagate out of the light source. A magnetic core is positioned around a portion of the chamber and is configured to generate plasma in the plasma generation region so that the plasma converges in the plasma confinement region.

A power delivery section is positioned around the magnetic core. A power supply includes a charging circuit, a pre-ionization circuit, and a solid state switching circuit having an output coupled to the power delivery section positioned around the magnetic core. The power supply is configured to isolate the charging circuit from the power delivery section and to generate a pre-ionization pulse through inductive coupling that causes the ionization of gas in the plasma generation region. The solid state switching circuit is configured to discharge a capacitance through an inductive coupling to form a plasma in the plasma generation region.

A method of generating extreme ultra-violet light according to the present teaching includes configuring a chamber comprising a high voltage region, a low voltage region, a plasma generation region that defines a plasma confinement region, and a port that allows light generated by the plasma to propagate out of the light source. A portion of the chamber is surrounded by a magnetic core configured to converge a plasma in the plasma confinement region. A charging pulse is generated. A pre-ionization pulse is then generated using inductive coupling that causes the ionization of gas in the plasma generation region independent of the charging pulse. A capacitance is then discharged through inductive coupling using a solid state switch to form a plasma in the plasma generation region from the ionized gas.

### BRIEF DESCRIPTION OF THE DRAWINGS

The present teaching, in accordance with preferred and exemplary embodiments, together with further advantages thereof, is more particularly described in the following detailed description, taken in conjunction with the accompanying drawings. The skilled person in the art will understand that the drawings described below are for illustration purposes only. The drawings are not necessarily to scale; emphasis is instead generally being placed upon illustrating principles of the teaching. The drawings are not intended to limit the scope of the Applicant's teaching in any way.

FIG. 1 illustrates a cross-section view of a known plasma chamber for generating a Z-pinch ultraviolet light.

FIG. 2 illustrates an ultraviolet light source that includes a solid-state pulsed power supply and power delivery section.

FIG. 3 illustrates a schematic diagram of a solid-state pulsed power and delivery system for an ultraviolet light source.

FIG. 4 illustrates plots of current through and voltage across a charging capacitor in a solid-state switch subsystem in a power supply according to the present teaching.

FIG. 5 illustrates a schematic diagram of a power supply for an ultraviolet light source that includes a solid-state pulsed power supply inductively coupled to a plasma load via a magnetic core 506 according to the present teaching.

FIG. 6 illustrates a graph of the timing of the combined pulse generated by the charging circuit, pre-ionization circuit, and solid state switching circuit in the solid-state pulsed power supply described in connection with FIG. 5.

FIG. 7 illustrates measured data for pre-ionization pulse current generated by the pre-ionization circuit described in connection with FIG. 5 as a function of time for different DC voltage values applied by the pre-ionization voltage power supply.

FIG. 8 illustrates measured data for extreme ultra-violet light optical power generated by extreme ultra-violet light sources with solid state switching power supplies according to the present teaching as a function of DC voltage values applied by the pre-ionization voltage power supply.

### DESCRIPTION OF VARIOUS EMBODIMENTS

The present teaching will now be described in more detail with reference to exemplary embodiments thereof as shown in the accompanying drawings. While the present teaching is described in conjunction with various embodiments and examples, it is not intended that the present teaching be limited to such embodiments. On the contrary, the present teaching encompasses various alternatives, modifications, and equivalents, as will be appreciated by those of skill in the art. Those of ordinary skill in the art having access to the teaching herein will recognize additional implementations, modifications, and embodiments, as well as other fields of use, which are within the scope of the present disclosure as described herein.

Reference in the specification to “one embodiment” or “an embodiment” means that a particular feature, structure, or characteristic described in connection with the embodiment is included in at least one embodiment of the teaching. The appearances of the phrase “in one embodiment” in various places in the specification are not necessarily all referring to the same embodiment.

It should be understood that the individual steps of the method of the present teaching can be performed in any order and/or simultaneously as long as the teaching remains operable. Furthermore, it should be understood that the apparatus and method of the present teaching can include any number or all of the described embodiments as long as the teaching remains operable.

Extreme ultraviolet (EUV) light sources play an important role in numerous optical measurement and exposure applications. It is desirable that these sources be configured to accommodate numerous use cases. One challenge is to generate high-power and high-brightness EUV light in a configuration with enough flexibility to allow integration with numerous applications and also exhibit high stability and high reliability.

Extreme ultraviolet radiation is referred to in numerous ways by those skilled in the art. Some skilled in the art sometimes referred to extreme ultraviolet radiation as high-energy ultraviolet radiation, which can be abbreviated as XUV. Extreme ultraviolet radiation generally refers to electromagnetic radiation that is part of the electromagnetic spectrum nominally spanning wavelengths from 1 nm to 20 nm. There is some overlap between extreme ultraviolet radiation and what is considered to be the optical spectrum. One particular EUV wavelength of interest is 13.5 nm because that wavelength is commonly used for lithography. Extreme ultraviolet radiation sources, according to the present teaching, are not limited to the generation of EUV radiation. As is known in the art, plasmas can be used to generate a wide spectral range of photons. For example, plasmas generated according to the present teaching can also be used to generate soft x-ray photons (SXR). This includes, for example, photons with wavelengths of less than 10 nm.

So-called Z-pinch plasmas, which have current in the axial direction, have been shown to be effective at producing EUV and SXR light. However, most known sources have employed electrodes to conduct high discharge currents into the plasma. These electrodes, which are typically in contact with high temperature plasma, can melt and produce significant debris, which is highly undesirable as it can greatly reduce the useful lifetime of the source.

Electrodeless approaches to generated EUV are desirable and fill a considerable market need. Such sources are available, for example, from Energetiq, a Hamamatsu Company, located in Wilmington, MA. These sources are based on a Z-pinch plasma, but avoid electrodes entirely by inductively coupling current into the plasma. The plasma in these EUV sources is magnetically confined away from the source walls, minimizing the heat load and reducing debris and providing excellent open-loop spatial stability, and stable repeatable power output. One challenge with known Z-pinch light sources is that their performance, especially in brightness, is limited by their power supplies because they use magnetic switches, which are highly undesirable, and not flexible or easily scalable.

One feature of the EUV sources of the present teaching is that they are versatile and support various applications with high brightness. In particular, EUV sources of the present teaching improve upon known Z-pinch designs because they can be optimized for peak power and/or for peak brightness as required by the user for a particular application. In addition, EUV sources of the present teaching have a more compact physical foot print and a more flexible component layout.

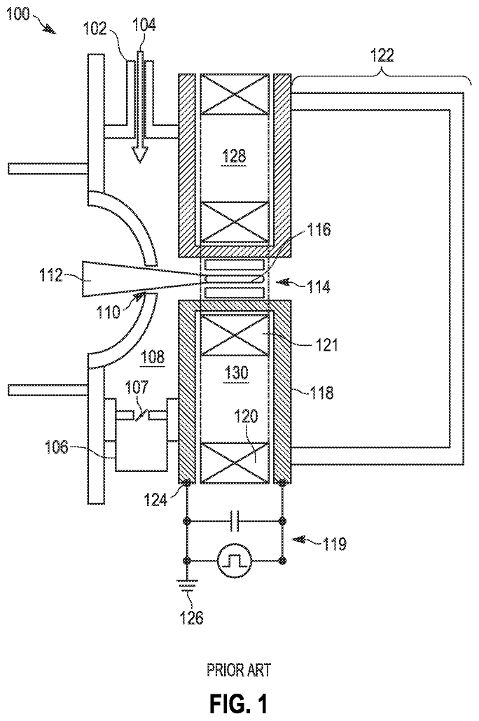

FIG. 1 illustrates a known plasma chamber 100 for generating a Z-pinch ultraviolet light. See, for example, U.S. patent application Ser. No. 17/676,712, entitled “Inductively Coupled Plasma Light Source”, which is assigned to the present assignee. The entire contents of U.S. patent application Ser. No. 17/676,712 are incorporated herein by reference.

The chamber for the ultraviolet light source 100 includes an interface 102 that passes a feed gas 104 into the chamber 100. A pump 106 is used to evacuate the chamber region 108 to a desired operating pressure and/or to control gas flow in the chamber 100 using a butterfly valve 107 or other means of controlling conductance. A port 110 is provided to pass EUV radiation 112 generated by the EUV plasma.

In various systems, the port 110 is configured to be adaptable for a user to attach to an application system (not shown) where the EUV radiation passes directly through the port 110. A plasma generation region 114 defines a plasma confinement region 116. The plasma confinement region 116 is formed by magnetic induction when a pulse forming and power delivery system 118 provides a current that interacts both actively and passively with magnetic cores 120, 121. A high voltage region 122 is attached to the plasma generation region 114. A low voltage region 124 has an outer surface that is coupled to a low voltage potential, which in some embodiments is ground 126 as shown in FIG. 1. A pulsed power supply 119 that uses magnetic switches is electrically coupled to the power delivery system 118. The chamber 100 also includes region 128, 130 between the inner and outer magnetic cores 121, 120 where the current carried by the inductively coupled plasma flows. During the operation of the Z-pinch plasma in this known chamber 100, the feed gas in the plasma generating region 114 is compressed by the electric pulses generated by the pulsed power supply 119, followed by an expansion of the gas after the pulse.

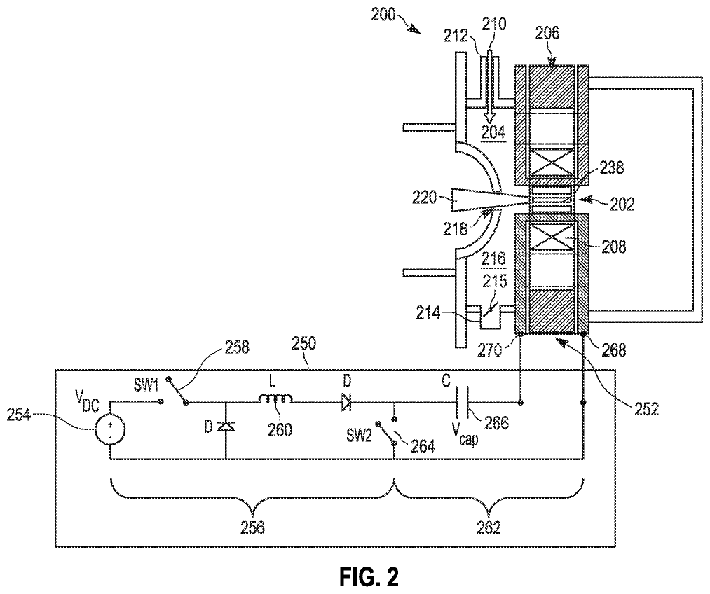

FIG. 2 illustrates an ultraviolet light source 200 that includes a solid-state pulsed power supply 250 and power delivery section 252. The source 200 is an inductively coupled design that uses magnetic confinement of the plasma in the plasma generation region 238 where a Z-pinch is generated away from the components of the chamber 204 of the ultraviolet light source 200 to provide high reliability and high stability. A flux excluder 206 is used to increase the confinement of magnetic flux in the power delivery section, thus reducing the inductance. In operation, one or more plasma loops flow through the flux excluder region 206 and through a plasma confinement region 202, making a plasma loop around the inner magnetic core 208. The plasma loops themselves do not produce significant EUV light

A target gas 210 enters through an interface 212 into the chamber 204. In some embodiments, the target gas is Xenon. A pump 214 is used to evacuate the chamber region 216 to a desired operating pressure. A valve, such as a butterfly valve 215, is used to control the pressure in the chamber region 216. A transparent port 218 is provided to pass EUV radiation, that is, EUV light 220 generated by the plasma. This port 218 can be, for example, any of the various kinds of ports described in connection with the port 110 of FIG. 1.

A solid-state pulsed power supply (PPS) 250 is used to drive current through the power delivery section 252 to a low voltage region to generate the plasma. In one specific embodiment, the low voltage region is ground. However, it should be understood that the low voltage region is not necessarily at ground potential. The solid-state pulse power supply 250 is connected to the power delivery section 252 at a high voltage side 268 and a low voltage side 270. In some configurations, a diameter of plasma generation region 238 is smaller than a diameter of a high voltage region electrically coupled to the high voltage side 268. The pulsed power system 250 includes a DC power supply 254 that provides a DC voltage (VDC) at an output. A resonant charging subsystem 256 with a resonant charging switch 258 and an inductor 260 is coupled to the output of the DC power supply 254. The resonant charging subsystem 256 is configured to approximately double the voltage provided by the DC power supply 254 at the capacitor 266. This is accomplished using inductive energy storage with the inductor 260 to effectively double the voltage provided by the DC power supply 254 at the capacitor 266. In other words, the resonant charging subsystem 256 and the capacitor 266 form a resonant charging circuit.

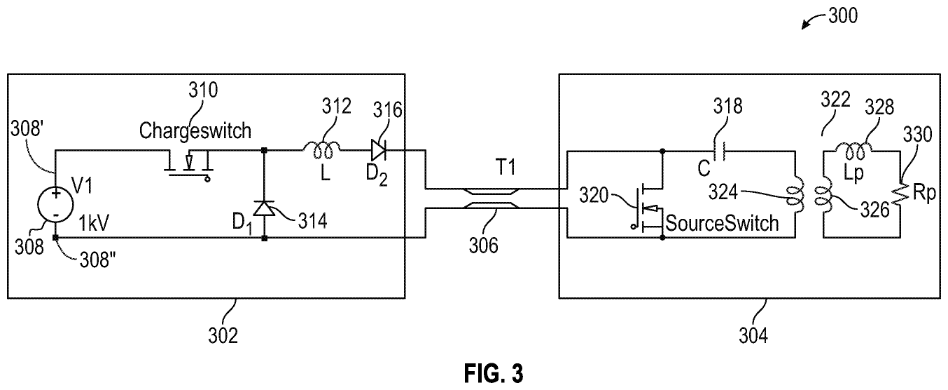

The solid-state pulsed power supply 250 also includes a solid-state switch subsystem 262 that includes a discharge switch 264 and at least one capacitor 266 that generates the current necessary to form a plasma. The at least one capacitor 266 is typically a plurality of capacitors as described in connection with FIG. 3. FIG. 3 illustrates a schematic diagram of a solid-state pulsed power and delivery system 300 for an ultraviolet light source. The system 300 includes a resonant charging subsystem 302, a solid-state switch subsystem 304, and a transmission line system 306 coupling the resonant charging subsystem 302 and the solid-state switch subsystem 304. The resonant charging subsystem 302 includes a DC power supply 308 that can be, for example, a 1 kV power supply as one particular embodiment that generates a high voltage in the range of about 500V to 1 kV. Other embodiments can have the DC power supply 308 operating in the several kV range with a positive output 308′ and a negative output 308″ The DC power supply 308 provides a DC voltage to the resonant charging switch 310, which in many embodiments, includes a high-power solid-state switch that switches the output voltage of the DC power supply 308. In recent years, there have been great advances in the performance of high-power solid-state device technology. For example, Heterojunction Bipolar Transistor (HBT), Insulated Gate Bipolar Transistor (IGBT), Silicon Carbide Metal-Oxide-Semiconductor Field-Effect Transistor (SiCFET), and Bi Metal-Oxide-Semiconductor Field-Effect Transistor (BiMOSFET) are examples of robust high-power and fast-switching solid-state switches that are useful for power supplies according to the present teaching. BiMOSFET devices are particularly useful because they combine the strengths of MOSFET devices with the strengths of IGBT devices to achieve a positive temperature coefficient of Vce (voltage difference between the collector and emitter) and Vf (forward voltage). BiMOSFET devices also advantageously feature low conduction losses making them particularly suitable for high-frequency and/or high-power density applications.

When the resonant charging switch 310 is closed, the voltage generated by the DC power supply 308 is applied to the inductor 312 that stores energy for the pulses. The inductor 312 is one or more inductors coupled in series that provides a large inductance value. For example, in some systems, the total inductance value of inductor 312 can be on the order of 1-10 micro-H or higher in some embodiments.

Diodes D1 314 and D2 316 prevent current passed by the resonant charging switch 310 from reversing and also provide a charging current that pre-ionizes the plasma, thereby sustaining the plasma loop. The resonant charging subsystem 302 is configured to approximately double the voltage provided by the DC power supply at the capacitor 318. We note that the resonant charging subsystem 302, transmission line 306, and capacitor 318 form the resonant charging circuit.

The transmission line system 306 couples the voltage generated by the resonant charging subsystem 302 to the solid-state switch subsystem 304. The solid-state switch subsystem 304 includes a capacitor 318 and a solid-state discharge switch 320. In many embodiments, the capacitor 318 is a bank of multiple parallel-connected capacitors that provides a relatively high capacitance value at comparatively low inductance. For example, in one specific embodiment, the total capacitance value of capacitor 318 can be on the order of 3,000 nF. With the specific embodiment described, the peak pre-pulse current is in the range of 380 Amps with a half sine wave charging time of in the 15-20 microsecond range.

The schematic diagram of a solid-state pulsed power and delivery system 300 shows the power delivery section 252 (FIG. 2) as the primary 324 and the plasma as the secondary 326 of the transformer 322. Current pulses generated by the solid-state switch subsystem 304 are applied to a primary 324 of the transformer 322 via the power delivery section 252. The plasma itself is modeled as the secondary 326 of the transformer 322 having both an inductive component 328 and a resistive component 330.

Pulsed operation of the solid-state pulsed power and delivery system 302 is accomplished by switching through two solid-state switches, the resonant charging switch 310 in the resonant charging subsystem 302 and the discharging switch 320 in the solid-state switch subsystem 350. The resonant charging switch 310 in the resonant charging subsystem 302 applies high-voltage pulses across the capacitor 318 or capacitor bank in the solid-state switch subsystem 304. When the resonant charging switch 310 is closed, current flows through the resonant charging subsystem 302 and charges the capacitor 318. The diodes D1 314 and D2 316 are configured to ensure the desired direction of current flow and are also configured so that a charging current is provided that pre-ionizes the plasma, thereby sustaining the plasma loop in between pulses. The charging voltage including the maximum charging voltage can be expressed with the below equations.

$${V}_{c} = {V}_{DC} ( 1 - cos ( \frac{t}{\sqrt{LC}} ) )$$

$${V}_{c} = 2 {V}_{DC}$$

$$at$$

$$t = π \sqrt{LC}$$

The pre-pulse current is given by the following equation:

$$i = \frac{{V}_{D C}}{\sqrt{\frac{L}{C}}} sin ( \frac{t}{\sqrt{LC}} )$$

The pre-ionization is important because Z-pinch operation requires a sustained plasma loop because continually ionized gas is necessary for proper function. The discharge switch 320 is closed when the maximum voltage across capacitor 318 is reached.

Referring to both FIGS. 2 and 3, the resulting discharge causes capacitor 318 to drive a current through the high voltage side 268 and the low voltage side 270 of the power delivery section 252. Consequently, the magnetic core 208 couples the current pulse to the plasma loops, resulting in a large current pulse in the plasma that forms loops that flow through the flux excluder region 206 and through the plasma confinement region 202, making a loop around the magnetic core 208. In some embodiments, at least three inductively coupled plasma loops converge in the plasma confinement region 202 to form a magnetically confined Z-pinch. The plasma confinement region 202 produces and emits nearly 100% of the EUV radiation generated by the plasma. The result is that the source 200 produces high quality EUV light 220 from a well-defined and stable pinch plasma confinement region 202. Importantly, the source 200 is a highly compact source compared with other known sources for generating stable pinch plasma suitable for light source applications. These features are made possible by the solid-state switching power supply of the present teaching.

Another feature of the present teaching is that the solid-state pulsed power system pulse forming and power delivery section 300 can be constructed with the power supply components on multiple circuit boards so that the power supply can be configured in a relatively small area compared with known switching power supply technologies.

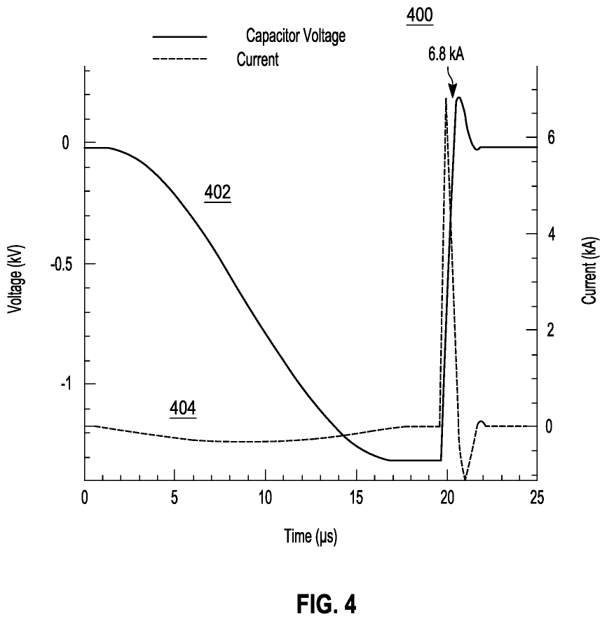

FIG. 4 illustrates plots 400 of current through and voltage across a charging capacitor in a solid-state switch subsystem in a power supply according to the present teaching. The plot 402 represents voltage in Volts across the charging capacitor in the solid-state switch subsystem as a function of time in microseconds. The plot 404 represents current in kAmps flowing through the charging capacitor as a function of time in microseconds. The plots 400 indicate that when the elapsed time reaches about 20 microseconds, a large voltage pulse is established, which can be on the order of about 1.3 kV with an associated peak current pulse of about 6.8 kA.

Thus, one important feature of the present teaching is that since the solid-state resonant charging switch 310 and the solid-state discharging switch 320 do not work on magnetic saturation like known power supplies for generating Z-pinched inductively coupled plasmas, they can be conveniently located inside the power supply unit itself. This allows designers to locate the switching devices next to the capacitors 320 on the switchboard itself, which has the advantage that it minimizes inductance. This is possible, at least in part, because the FET switching devices themselves are compact especially when compared with magnetic switches. Such a configuration is not possible in known systems that use coupling core magnetic circuits as simplicity and space requirements make such configurations impractical for a commercial product.

There are many advantages of the solid-state pulsed power system pulse forming and power delivery second according to the present teaching. One advantage is that by using the pulsed power system according to the present teaching to drive and contain the plasma, the plasma source 200 (FIG. 2) operates without the use of electrodes that are commonly used to conduct discharge current to the plasma in known systems.

Another advantage of the solid-state pulsed power system of the present teaching is that the resonant charging with the inductive energy storage and voltage doubling as described herein allows for much higher frequency operation compared with prior art systems. For example, when solid state switching devices are used for switches 310 and 320, a frequency of operation in the range of 10 KHz can be easily achieved, and significantly higher frequency operation is possible. Furthermore, when solid-state switching devices are used, a wide range of pulse energies can be obtained. For example, with commercially available devices, the pulse energy can be in the range of several Joules. Consequently, with the higher frequency of operation and higher pulse energies, much higher brightness can be achieved in a light source using the solid-state pulsed power system of the present teaching.

Yet another advantage of the solid-state pulsed power system of the present teaching is that the power supply can generate a controllable amount of charging current pulses that can be used to produce a pre-ionization current that is sufficient to obtain desired Z-pinching conditions. The solid-state pulsed power systems of the present teaching are highly adjustable to generate a wide range of pre-ionization pulse conditions. Suitable pre-ionization pulses are much smaller than the pulses primarily used to generate the plasma. Typically, the pre-pulse will have a maximum current in the sub kiloamp range whereas the main pulse will have a maximum current of 5-10 kA. However, these power systems can generate highly adjustable pulses to provide flexible operation.

Thus, another feature of the power supplies of the present teaching is that these power supplies can generate pulses with highly adjustable dwell time. By dwell time, we mean the delay after the charging time and before the main capacitor discharge. One measure of charging time is the time that the switches 310 in the resonant charging subsystem 302 are closed. In one specific embodiment, the dwell time is controllable from below one microsecond to over fifty microseconds in order to provide more desirable and varied operating conditions.

As described herein, pre-ionization is necessary to obtain favorable Z-pinch plasma generation conditions. Also, as described herein, pre-ionization according to the present teaching is accomplished by generating a pre-pulse from current leakage for charging where the amplitude of the pre-pulse is much less than the main pulse that generates the Z-pinched plasma. The dwell time, which is roughly the time between the pre-pulse and the main pulse is chosen to provide the desired Z-pinching conditions.

One skilled in the art will appreciate that there are numerous methods of generating ultraviolet light according to the present teaching. These methods generally provide a feed gas to a plasma confinement region 202 in a plasma chamber 204 (FIG. 2). Some methods also apply a feed gas or a second gas to a port positioned at one or more of various locations. A high voltage pulse is applied to a high voltage region 268 connected to the plasma confinement region 202 in the plasma chamber 204 relative to a low voltage region 270.

A train of voltage pulses is generated by the solid-state pulsed power supply 300 and is applied to at least one capacitor 318 electrically connected across a power delivery section 304 surrounding a magnetic core 208 that is positioned around the plasma confinement region 202. The train of voltage pulses causes at least one capacitor 318 to charge until a voltage maximum is reached and the solid state discharge switch 320 is closed resulting in at least one capacitor discharging and causing the magnetic core 208 to couple current pulses into the plasma confinement region 202, thereby forming a plasma in a loop where the plasma is sustained between voltage pulses by a charging current that causes pre-ionization as described herein. The resulting plasma generates ultraviolet light that propagates through a transparent port 218 positioned adjacent to the plasma confinement region 202.

There are numerous performance advantages inherent in the solid state switching pulsed power system according to the present teaching that is used to drive current pulses. One advantage is that such systems are not limited by eddy current and hysteresis losses in the magnetic switch core region like traditional magnetically switched systems. Importantly, the frequency of current pulses can be greatly increased compared with known systems that use magnetically switched power supplies. Also, the energy per pulse can be significantly increased compared with known systems that use magnetically switched power supplies. The result of these enhancements is an increase in the production of EUV radiation and much more flexible operation.

However, the solid-state pulsed power system described in connection with FIGS. 2 and 3 generates a relatively large current for a time duration that is on the order of about 17 microseconds. The result is that more plasma can be expelled from the plasma pinch region than necessary, which can result in an unnecessary loss of performance. In addition, the solid-state pulsed power system described in connection with FIGS. 2 and 3 lacks adjustability.

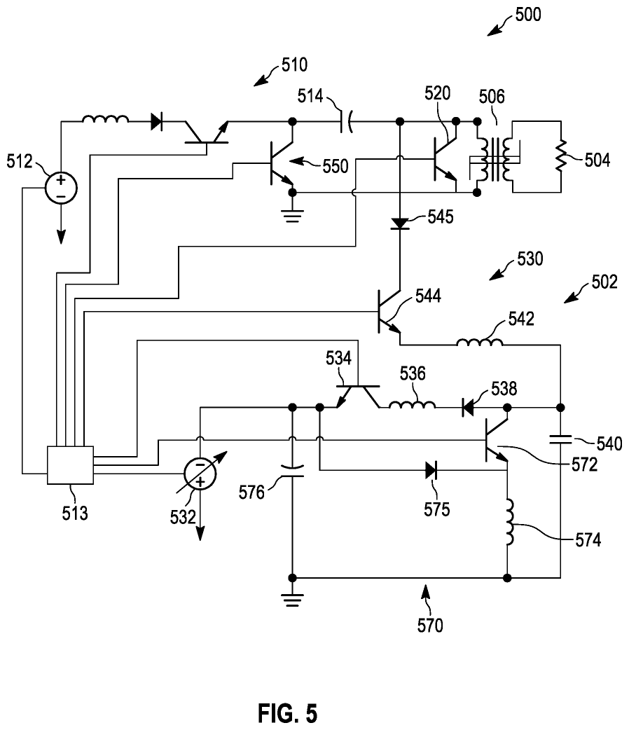

FIG. 5 illustrates a schematic diagram of a power supply for an ultraviolet light source 500 that includes a solid-state pulsed power supply 502 inductively coupled to a plasma load 504 via a magnetic coupling core 506 according to the present teaching. The plasma load 504 is shown as a resistance 504 and the magnetic coupling core 506 is shown as a transformer. The solid-state pulsed power supply 502 includes a resonant charging circuit 510, a pre-ionization circuit 530, a solid state switching circuit 550, and an energy recycler circuit 570. One feature of the solid-state pulsed power supply 502 is that the pre-ionization circuit 530 and the solid state switching circuit 550 are independent and essentially isolated from the resonant charging circuit 510.

The resonant circuit 510 is coupled to the voltage supply 512 that generates a positive DC voltage. In some configurations, a controller 513 is coupled to the voltage supply that controls the operation of the voltage supply 512. In the embodiment shown, the resonant circuit 510 includes an inductor in series with a diode, which is in series with a transistor switch. The transistor switch can be controlled by the controller 513. An energy storage capacitor 514 is coupled to the resonant circuit 510. For example, in one particular embodiment, the energy storage capacitor 514 is a 3 uF capacitor. The energy storage capacitor 514 is charged with a relatively slow positive-going pulse. This slow charging pulse is blocked from the plasma load 504 by the saturated state of the coupling core 506 and an external shorting switch (not shown).

In one embodiment, a transistor switch 520 is electrically connected in parallel with the power delivery section positioned around the magnetic coupling core 506. The transistor switch 520 diverts the charging current away from the coupling core 506 and thus, the resulting plasma during the charging phase. That is, the switch 520 can prevent the charging current generated by the charging circuit 510 from passing through the magnetic coupling core 506 and into the resulting plasma. When activated, the switch 520 shunts excess current away from the resulting plasma. The switch 520 is subsequently deactivated before the capacitor discharging phase. This is useful for some methods according to the present teaching as the shunt will reduce excess current in the magnetic coupling core 506 that negatively disturbs the pre-pulse plasma conditions.

In some methods according to the present teaching, excess current in the coupling core 506 that negatively disturbs the pre-pulse plasma conditions is reduced by biasing the power delivery section positioned around the magnetic coupling core 506 with a DC current such that the coupling core 506 is placed in its magnetically saturated state. When the magnetic coupling core 506 is saturated in the correct direction, the magnetic coupling core 506 presents a very low impedance to the current charging the capacitor 514, which diverts the charging current away from the resulting plasma. These two methods of reducing excess current in the coupling core 506 can substantially prevent any of the charging current from disturbing the plasma conditions.

The pre-ionization circuit 530 includes a variable negative voltage power supply 532 having an output that is coupled to a resonant charging switch 534, which in the embodiment shown is a solid state switch. The resonant charging switch 534 can be controlled by the controller 513 via a fiber-optic cable. The resonant charging switch 534 is coupled to a resonant circuit comprising a series combination of an inductor 536, a diode 538, and a pre-ionization capacitor 540. For example, in one specific embodiment, the pre-ionization capacitor 540 has a capacitance of about 0.44 uF and the inductor 536 has an inductance of about 47 uH. The pre-ionization circuit 530 resonantly charges the pre-ionization capacitor 540 to generate a half-sine pre-ionization voltage pulse. The amplitude of the half-sine pre-ionization pulse is adjustable by adjusting the amplitude of the negative voltage output of the power supply 532. In one specific embodiment, the negative voltage can be on the order of about 200V.

The solid state switching circuit 550 includes a solid state switch, which for example can be Heterojunction Bipolar Transistor, Insulated Gate Bipolar Transistor, Silicon Carbide Metal-Oxide-Semiconductor Field-Effect Transistor, or a Bi Metal-Oxide-Semiconductor Field-Effect Transistor (BiMOSFET). Such switches are all capable of switching high powers at high speeds. The switch or switches in the solid state switching circuit can be controlled by a microprocessor coupled to the switch via a fiber-optic cable.

The solid state switching circuit 550 is directly coupled to the charging circuit 510. The transformer or coupling core 506 is coupled to the pre-ionization circuit 530 via a pre-ionization switch 544 that is electrically connected to the storage capacitor 514 through a diode 545 that blocks reverse current from the pre-ionization circuit 530. When the pre-ionization switch 544 is closed, a half-sine pre-ionization pulse is generated from the energy in the pre-ionization capacitor 540 and a pre-ionization inductor 542. In some configurations, the solid state switching circuit 550 and the pre-ionization switch 544 are controlled by the controller 513. The pre-ionization inductor 542 is 0.8 uH in one particular embodiment. Then the solid state switching circuit 550 energizes the solid state switch so that an ionizing pulse is initiated causes a negative current pulse to be applied to the power delivery section positioned around the coupling core 506 and plasma load 504. Importantly, this method of generating the ionizing pulse isolates the charging circuit 510 from the pre-ionization circuit 530 and the solid state switching circuit 550.

The resonant energy recycler circuit 570 includes a solid state recycler switch 572, a recycler inductor 574, and a recycler capacitor 576. In the example described herein, the inductor is on order of 230 uH. The switch 572 can be controlled by the controller 513. In operation, the energy recycler circuit 570 recovers excess electrical energy from the pre-ionization capacitor 540 by transferring the electrical energy to the recycler capacitor 576. This excess electrical energy can be recovered after each pulse. The excess electrical energy can then be recycled by transferring from the recycler capacitor 576, to the recycler inductor 574, and then back to the pre-ionization capacitor 540.

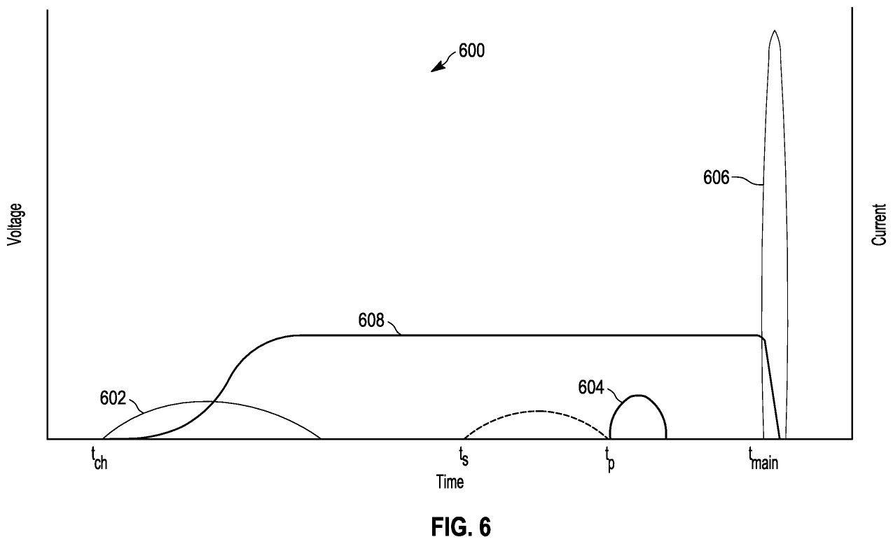

FIG. 6 illustrates a graph 600 of the timing of the combined pulses generated by the charging circuit 510, pre-ionization circuit 530, and solid state switching circuit 550 in the solid-state pulsed power supply described in connection with FIG. 5. Referring to both FIGS. 5 and 6, the operation of the solid-state pulsed power supply according to the present teaching is described. The charging circuit 510 applies a positive going current pulse 602 at time t_{ch} to charge capacitor 514 to a desired value. One feature of the solid state pulsed power supply of the present teaching is that the charging circuit 510 is isolated from the plasma load 504 by the switch 520 and by the DC bias of the coupling core 506. The switch 520 can be controlled by the controller 513. The solid state switch in the switching circuit 550 is deactivated during the duration of the positive going current pulse and the voltage on capacitor 514 remains unchanged. Thus, the charging current pulse does not cause any current to be generated in the plasma load.

The setup of the pre-ionization pulse 604 begins at time tₛ when the resonant charging switch 534 energizes and begins resonantly charging the pre-ionization capacitor 540 with the inductor 536. At one half the resonant period, which is determined by the LC combination of inductor 536 and the capacitor 540, the pre-ionization capacitor 540 is fully charged. In addition, the voltage at pre-ionization capacitor 540 doubles that of the input voltage generated by the variable negative voltage power supply 532. In the example described herein, where the pre-ionization capacitor 540 has a capacitance of about 0.44 uF and the inductor 536 has an inductance of about 47 uH, the resonant period is on order of 14 microseconds.

The pre-ionization pulse 604 begins at time tₚ when the pre-ionization switch 544 energizes. The switch 544 can be controlled by a microprocessor coupled to the switch via a fiber-optic cable. The energization begins a discharge of the pre-ionization capacitor 540 through the pre-ionization inductor 542, thereby creating a current pulse that couples to the plasma load 504 through the coupling core 506. The period of the current pulse is set by the capacitance of the pre-ionization capacitor 540 and by the inductance of the pre-ionization inductor 542. At one half of the period of the inductance-capacitance combination, which for the example presented herein is two microseconds, the diode 545 blocks the reversing current. Since the plasma load 504 presents a small impedance to the inductance-capacitance combination circuit 542, 540, little energy is dissipated in the plasma load 504, and the voltage in the pre-ionization capacitor 540 reverses almost completely. With the diode 545 blocking reverse current, the leftover energy is stored in the now positively charged pre-ionization capacitor 540. For the example described herein the voltage on the pre-ionization capacitor 540 will be in the range of positive 380V.

The main switching pulse 606 is initiated when the switching circuit 550 energizes the switch at time tₘₐᵢₙ causing the capacitor 514 to discharge through the coupling core 506 and into plasma load 504. For the example presented the discharge current in the main pulse 606 is in the range of 10-20 kA.

The pre-ionization accomplished by the solid state switching power supplies of the present teaching essentially provides an additional tuning parameter before the application of the main current pulse that can be advantageously used for various applications. In particular, when generating Z-pinched plasma, pre-ionization is useful to create favorable plasma conditions that aid the implosion. Some of the plasma conditions include homogeneity and a conductive plasma state which together allow the current to flow uniformly in the plasma. Also, maintaining a conductive plasma is important for maintaining the plasma loops which carry current to the Z-pinch region. In configuration where the plasma is not confined in the Z-direction at the ends of the pinch, the joule heated plasma can escape axially out of the pinch region, during the pre-ionization pulse phase.

In this configuration, where the plasma is not confined in the Z-direction at the ends of the pinch, the Joule heated plasma can escape axially out of the pinch region, during the pre-ionization pulse phase. Thus, the pre-ionization pulse can effectively be used to tune the plasma conditions to create a xenon density ideal for high EUV radiation production. By using an adjustable pre-ionization pulse, the density can be reduced locally in the pinch region until an optimum extreme ultra-violet optical power is reached. For example, a pre-ionization pulse current used is essentially a half sine wave of duration two us with a delay of 3.5 us before the main pulse.

The shape and amplitude of the pre-ionization pulse is determined by the values of the pre-ionization capacitor 540 and the pre-ionization inductor 542. Given the impedance of the plasma, these capacitance and inductance values are essentially pre-determined. In the example described herein, the energy required to drive 100 Amps in the plasma with the desired shape is about 70 mJ per pulse. If a simple resistance is used to charge the pre-ionization capacitor 540, the solid state switching circuit 550 would dissipate several hundred watts, and with varying operating conditions, could easily exceed 1 kW of energy that is essentially wasted energy. Consequently, there is a need for energy recycling.

One aspect of the present teaching is the integration of an energy recycling circuit with the solid-state pulsed power supply described herein. The energy recycler circuit 570 recycles the excess energy stored in the pre-ionization capacitor 540 before the next pulse is initiated. The solid state recycler switch 572 energizes at a time which is after tₘₐᵢₙ (not shown in FIG. 6) but before the initiation of the next pulse. Energizing the solid state recycler switch 572 initiates a resonant charge transfer between the pre-ionization capacitor 540 and the recycler inductor 574. The period of the resonant charge transfer is set by the value of the recycler inductance 574 and the value of the pre-ionization capacitor 540. For the example described herein, the period is about 63 microseconds.

At the one quarter period of the oscillation of the recycler inductor 574 and the pre-ionization capacitor 540, which is 16 microseconds in the example described herein, the solid state recycler switches 572 is opened. At the time the recycler switch 572 opens, the voltage across the pre-ionization capacitor 540 is zero and the current through the recycler inductor 574 is at its maximum. For example, the current through the recycler inductor 574 can be as much as 40 Amps or more depending on the particular operating conditions.

When the solid state recycler switch 572 opens, it reverses current flows through the recycler inductor 574 as the magnetic field collapses. The reversal of the current forces the diode 575 into conduction, which linearly discharges the recycler inductor 574 into the recycler capacitor 576. The voltage 608 across the recycler capacitor 576 is shown in FIG. 6. The capacitance of the recycler capacitor 576 is typically much greater than the capacitance of the pre-ionization capacitor 540 to facilitate this discharge. This completes the energy recycler pulse, recapturing the energy deposited in the pre-ionization capacitor 540 after the pre-ionization pulse terminates and is stored during the main pulse 606. Using the energy recycling according to the present teaching, the overall electrical efficiency of the pulse generating system has been shown to increase by more than 10% in practice.

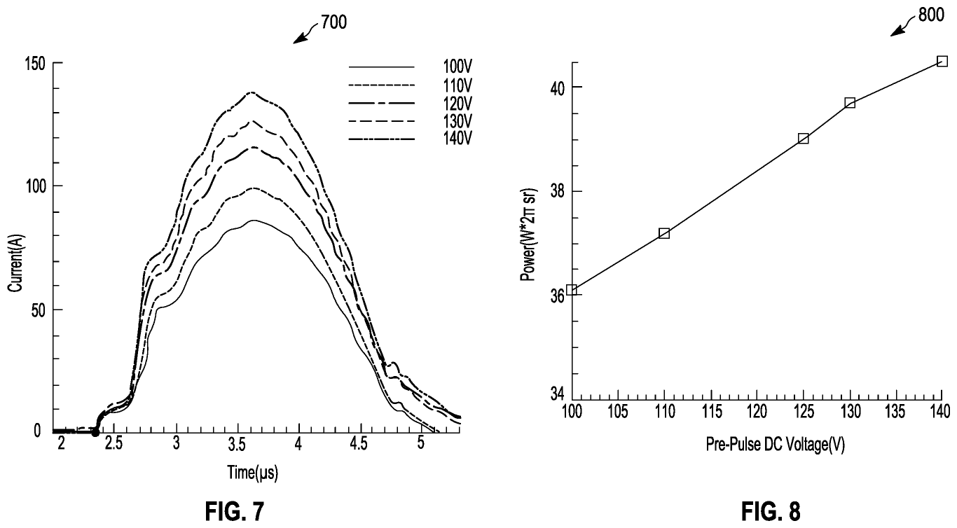

FIG. 7 illustrates measured data 700 for pre-ionization pulse current generated by the pre-ionization circuit 530 described in connection with FIG. 5 as a function of time for different DC voltage values applied by the pre-ionization voltage power supply 532. The current is shown in Amps and the time is shown in microseconds. These measured data show that the pre-ionization pulse current increases as the voltage applied by the pre-ionization voltage power supply 532 increases.

FIG. 8 illustrates measured data 800 for extreme ultra-violet light optical power generated by extreme ultra-violet light sources with solid state switching power supplies according to the present teaching as a function of DC voltage values applied by the pre-ionization voltage power supply 532. The power is shown in Watts into 2PI steradians. These measured data show that the power generated by the extreme ultra-violet light sources increases with increasing DC voltage values applied by the pre-ionization voltage power supply 532.

### EQUIVALENTS

While the Applicant's teaching is described in conjunction with various embodiments, it is not intended that the Applicant's teaching be limited to such embodiments. On the contrary, the Applicant's teaching encompasses various alternatives, modifications, and equivalents, as will be appreciated by those of skill in the art, which may be made therein without departing from the spirit and scope of the teaching.

What is claimed is:

1. A light source comprising:
a) a chamber comprising a high voltage region, a low voltage region, a plasma generation region that defines a plasma confinement region, and a port that allows light generated by the plasma to propagate out of the light source;
b) a magnetic core positioned around a portion of the chamber, the magnetic core configured to generate a plasma in the plasma generation region, wherein the plasma converges in the plasma confinement region;
c) power delivery section positioned around the magnetic core; and
d) a power supply comprising
i) a resonant charging circuit that generates a charging pulse;
ii) a pre-ionization circuit electrically connected to the power delivery section and being configured to isolate the charging circuit from the plasma generation region and to generate a pre-ionization pulse through inductive coupling that causes ionization of gas that forms a pre-ionized plasma in the plasma generation region; and
iii) a solid state switching circuit having an output coupled to the power delivery section positioned around the magnetic core, the switching circuit configured to discharge a capacitance through inductive coupling to form a magnetically confined Z-pinched plasma in the plasma generation region.

2. The light source of claim 1 wherein the charging circuit is configured to generate a positive-going voltage pulse that charges a capacitor.

3. The light source of claim 1 wherein the charging current is isolated from effects of the magnetic core.

4. The light source of claim 1 further comprising a controller coupled to the power supply, the controller controlling operation of the resonant charging circuit and the pre-ionization circuit.

5. The light source of claim 1 further comprising a controller coupled to the solid state switching circuit.

6. The light source of claim 5 wherein the controller is fiber coupled to the solid state switching circuit.

7. The light source of claim 1 wherein the pre-ionization circuit comprises a resonant charging circuit.

8. The light source of claim 1 wherein the pre-ionization circuit comprises an energy recycler circuit.

9. The light source of claim 1 wherein the pre-ionization circuit comprises an adjustable voltage power supply.

10. The light source of claim 1 wherein the pre-ionization circuit comprises a solid state switch.

11. The light source of claim 10 wherein the solid state switch is a field effect transistor (FET).

12. The light source of claim 10 wherein the solid state switch is a Bi Metal-Oxide-Semiconductor Field-Effect Transistor (BiMOSFET) device.

13. The light source of claim 10 wherein the solid state switches is an Insulated Gate Bipolar Transistor (IGBT).

14. The light source of claim 10 wherein the power supply further comprises a switch electrically connected in parallel with the power delivery section positioned around the magnetic core, the switch being configured to divert the charging current away from the power delivery section.

15. A method of generating extreme ultra-violet light, the method comprising:
a) configuring a chamber comprising a high voltage region, a low voltage region, a plasma generation region that defines a plasma confinement region, and a port that allows light generated by the plasma to propagate out of the light source;
b) surrounding a portion of the chamber with a magnetic core configured to converge a plasma in the plasma confinement region;
c) generating a charging pulse;
d) generating a pre-ionization pulse using inductive coupling that causes ionization of gas in the plasma generation region independent of the charging pulse; and
e) discharging a capacitance through inductive coupling using a solid state switch to form a plasma in the plasma generation region from the ionized gas.

16. The method of claim 15 wherein the charging pulse is a positive going pulse.

17. The method of claim 15 wherein the generating of the charging pulse is isolated from the plasma.

18. The method of claim 15 further comprising controlling timing of the generation of the charging pulse by triggering the solid state switch with a signal provided by an optical fiber.

19. The method of claim 15 wherein the generating of the pre-ionization pulse comprises resonant charging.

20. The method of claim 15 wherein the generating a charging pulse comprises resonant charging.

21. The method of claim 15 further comprises energy recycling.

22. The method of claim 15 further comprising diverting current away from the power delivery section positioned around the magnetic core, thereby shunting excess current away from the plasma.
